(19) United States
(12) Patent Application Publication
(10) Pub. No.: US 2025/0140548 A1
(43) Pub. Date: May 1, 2025

(54) PROCESSING SOLUTION, METHOD FOR PROCESSING SUBSTRATE, AND METHOD FOR MANUFACTURING SEMICONDUCTOR SUBSTRATE

(71) Applicant: TOKYO OHKA KOGYO CO., LTD., Kanagawa (JP)

(72) Inventors: Jun IIOKA, Kanagawa (JP); Aaron GELL, Hillsboro, OR (US); Takahiro ETO, Kanagawa (JP)

(21) Appl. No.: 18/924,413

(22) Filed: Oct. 23, 2024

Related U.S. Application Data
(60) Provisional application No. 63/593,081, filed on Oct. 25, 2023.

(51) Int. Cl. H01L 21/02; B08B 3/08; C11D 7/06; C11D 7/10; C11D 7/32; C11D 7/50; C23C 16/06; C23C 16/34; C23C 16/56

(52) U.S. Cl. CPC H01L 21/02068; B08B 3/08; C11D 7/06; C11D 7/10; C11D 7/3281; C11D 7/5009; C23C 16/06; C23C 16/34; C23C 16/56

(57) ABSTRACT

There are provided a processing solution, including: (a) a compound capable of releasing a fluoride anion or a salt thereof; (b) a water-soluble organic solvent; (c) water; and (d) a nitrogen-containing aromatic compound, in which an anion content of the nitrogen-containing aromatic compound at 25° C. is 5 ppm or more and 30 ppm or less; a method for processing a substrate; and a method for manufacturing a semiconductor.

### TECHNICAL FIELD

The present invention relates to a processing solution, a method for processing a substrate, and a method for manufacturing a semiconductor substrate.

### BACKGROUND ART

Semiconductor elements and liquid crystal panel elements such as ICs, LSIs, etc. are manufactured, for example, by: (i) uniformly applying a resist on a metal film, an insulating film such as a SiO₂ film, etc. that have been CVD-deposited on a substrate; (ii) selectively performing exposure and development processing on the substrate to form a resist pattern; (iii) with the pattern as a mask, selectively etching the substrate on which the metal film, insulating film such as a SiO₂ film, etc. have been CVD-deposited to form fine circuits; and (iv) then removing unnecessary regions of the resist layer, and the like. In addition to CVD, the above metal film can be formed by ALD, CVC, PVD, sputtering, metal plating, or the like.

As the above metal film, various kinds of metal films are used. These metal films are formed in a single layer or multiple layers on the substrate.

On the other hand, with the recent increase in density of integrated circuits, dry etching, which allows fine etching with higher density, has become mainstream. By performing the etching processing, residues such as an altered film, etc. or residues derived from another component may remain on sides, bottoms, etc. of the pattern. In addition, depositions are generated when the metal film is scraped during the etching. If the residues and depositions are not sufficiently removed, they cause problems such as a decrease in the production yield of semiconductors. Therefore, a processing solution (also called a cleaning solution, stripping solution, etc.) is used to remove such residues or depositions.

Dry etching residues are conventionally removed by a cleaning process. As a cleaning solution for removing dry etching residues, a cleaning solution containing peroxide as a residue removing agent is used (for example, see Patent Document 1).

### PATENT DOCUMENT

Patent Document 1: International Publication No. WO2016/076033

### SUMMARY OF THE INVENTION

However, a wide variety of metals are used for the above-mentioned substrate depending on the kinds of metal and insulating film formed on the substrate, the kind of resist used, and the like. Therefore, depending on the kind of metal used, the anticorrosion properties and etching properties may be insufficient, and there is room for further improvement of processing solutions in accordance with the kind of metal used. However, the current situation is that such detailed consideration has not been taken. As a result of intensive studies focusing on the current situation, the present inventor found that there was room for further improvement, particularly in achieving both the anticorrosion properties of copper and the etching properties of aluminum.

The present invention has been made in view of the above circumstances, and it is an object of the present invention to provide a processing solution, a method for processing a substrate, and a method for manufacturing a semiconductor substrate, which are excellent in both anticorrosion properties of copper and etching properties of aluminum.

As a result of intensive studies to achieve the above object, the present inventors have found a processing solution, including: (a) a compound capable of releasing a fluoride anion or a salt thereof; (b) a water-soluble organic solvent; (c) water; and (d) a nitrogen-containing aromatic compound, in which an anion content of the nitrogen-containing aromatic compound at 25° C. is 5 ppm or more and 30 ppm or less, and have thus completed the present invention. That is, the present invention is as follows:

<1> A processing solution, including: (a) a compound capable of releasing a fluoride anion or a salt thereof; (b) a water-soluble organic solvent; (c) water; and (d) a nitrogen-containing aromatic compound, in which an anion content of the nitrogen-containing aromatic compound at 25° C. is 5 ppm or more and 30 ppm or less.

<2> The processing solution according to <1>, further including: (e) ammonium hydroxide.

<3> The processing solution according to <1>, in which (b) the water-soluble organic solvent includes at least one selected from the group consisting of: dimethyl sulfoxide, N,N-dimethylformamide, N,N-dimethylacetamide, N-methyl-2-pyrrolidone, 1,3-dimethyl-2-imidazolidinone, ethylene glycol, and diethylene glycol monobutyl ether.

<4> The processing solution according to <1>, in which (d) the nitrogen-containing aromatic compound includes at least one selected from the group consisting of: an imidazole ring-containing compound, a triazole ring-containing compound, a carbazole ring-containing compound, a pyridine ring-containing compound, a pyrimidine ring-containing compound, a tetrazole ring-containing compound, a pyrazole ring-containing compound, a purine ring-containing compound, and a phenanthroline ring-containing compound.

<5> The processing solution according to <1>, in which a total solvent content is 60% by mass or more and 99.9% by mass or less.

<6> The processing solution according to <1>, in which the processing solution is a solution for processing a substrate after etching, and the substrate includes a first metal atom-containing layer containing a copper atom, and a second metal atom-containing layer containing an aluminum atom or a cobalt atom.

<7> The processing solution according to <1>, in which the processing solution is a solution for processing a substrate after etching, and the substrate includes a first metal atom-containing layer containing a copper atom, a second metal atom-containing layer containing an aluminum atom, and a third metal atom-containing layer containing a cobalt atom.

<8> A method for processing a substrate, including: processing a substrate after etching using the processing solution according to <1> at a temperature of 20° C. or more and less than 30° C., in which the substrate includes a first metal atom-containing layer containing a copper atom, and a second metal atom-containing layer containing an aluminum atom or a cobalt atom.

<9> A method for processing a substrate, including: processing a substrate after etching using the processing solution according to <1> at a temperature of 20° C. or more and less than 30° C., in which the substrate includes a first metal atom-containing layer containing a copper atom, a second metal atom-containing layer containing an aluminum atom, and a third metal atom-containing layer containing a cobalt atom.

<10> A method for manufacturing a semiconductor substrate, including: etching a substrate; ashing the etched substrate; and processing the ashed substrate using the processing solution according to <1> at a temperature of 20° C. or more and less than 30° C., in which the substrate includes a first metal atom-containing layer containing a copper atom, and a second metal atom-containing layer containing an aluminum atom or a cobalt atom.

<11> A method for manufacturing a semiconductor substrate, including: etching a substrate; ashing the etched substrate; and processing the ashed substrate using the processing solution according to <1> at a temperature of 20° C. or more and less than 30° C., in which the substrate includes a first metal atom-containing layer containing a copper atom, a second metal atom-containing layer containing an aluminum atom, and a third metal atom-containing layer containing a cobalt atom.

The present invention can provide a processing solution, a method for processing a substrate, and a method for manufacturing a semiconductor substrate, which are excellent in both anticorrosion properties of copper and etching properties of aluminum.

### BRIEF DESCRIPTION OF THE DRAWINGS

FIG. 1 is a cross-sectional view illustrating an example of an element after dry etching to be cleaned.

### DETAILED DESCRIPTION OF THE INVENTION

Hereinafter, an embodiment for carrying out the present invention (hereinafter simply referred to as “the present embodiment”) will be described in detail. The present embodiment below is an example for explaining the present invention, and it is not intended to limit the present invention to the following description. The present invention may be implemented with any appropriate modification within the scope of its gist.

In the drawings, the same elements are denoted by the same reference signs, and duplicate description will be omitted. In addition, the positional relationships such as top, bottom, left, and right are based on those illustrated in the drawings unless otherwise specified. Further, the dimensional ratios in the drawings are not limited to the illustrated ratios.

### <Processing Solution>

A processing solution according to the present embodiment is a processing solution, including: (a) a compound capable of releasing a fluoride anion or a salt thereof; (b) a water-soluble organic solvent; (c) water; and (d) a nitrogen-containing aromatic compound, in which an anion content of the nitrogen-containing aromatic compound at 25° C. is 5 ppm or more and 30 ppm or less. By using the processing solution, it is surprisingly possible to at least achieve an effect that both anticorrosion properties of copper and etching properties of aluminum are excellent.

The processing solution according to the present embodiment can be suitably used as a processing solution for removing an etching residue containing an inorganic substance. In that case, it can be suitably used as a processing solution for cleaning a semiconductor, etc.

The inorganic substance here in the present embodiment refers to a compound containing a metal, and examples thereof may include a metal, a metal oxide, a metal nitride, a metal chloride, a metal fluoride, and the like. That is, the processing solution according to the present embodiment is expected to have excellent anticorrosion properties and etching properties described above and also to efficiently remove an etching residue containing such an inorganic substance. Examples of the inorganic substance other than metals may include silicon (Si); an oxide (SiOₓ; Unless otherwise specified, x represents a number.), a nitride (SiNₓ), a chloride (SiClₓ), and a fluoride (SiFₓ) thereof, and the like.

Regarding the removal of residue, for example, the processing solution according to the present embodiment can be expected to efficiently remove a residue contained in a hard mask layer (HM layer) and another layer. In addition, the processing solution according to the present embodiment is also expected to efficiently remove an inorganic substance-containing residue that is derived from a metal wiring layer that contains one selected from the group consisting of a metal described below, and a metal oxide, a metal nitride, a metal chloride, and a metal fluoride thereof.

Examples of the metal may include one of metals such as molybdenum (Mo), tungsten (W), ruthenium (Ru), copper (Cu), gold (Au), silver (Ag), iron (Fe), nickel (Ni), aluminum (Al), lead (Pb), zinc (Zn), tin (Sn), tantalum (Ta), magnesium (Mg), cobalt (Co), bismuth (Bi), cadmium (Cd), titanium (Ti), zirconium (Zr), antimony (Sb), manganese (Mn), beryllium (Be), chromium (Cr), germanium (Ge), vanadium (V), gallium (Ga), hafnium (Hf), indium (In), niobium (Nb), rhenium (Re), thallium (Tl), etc.; a metal oxide, a metal nitride, a metal chloride, a metal fluoride, etc. thereof; and the like.

Examples of the metal oxide may include a metal oxide of the metal atoms described above. Specific examples of the metal oxide may include, but are not limited to, TiOₓ, TaOₓ, CuOₓ, CoOₓ, RuOₓ, AlOₓ, WOₓ, MoOₓ, AuOₓ, AgOₓ, FeOₓ, NiOₓ, and the like (Unless otherwise specified, x represents a number.).

Examples of the metal nitride may include a metal nitride of the metal atoms described above. Specific examples of the metal nitride may include, but are not limited to, TiNₓ, TaNₓ, CuNₓ, CoNₓ, RuNₓ, AlNₓ, WNₓ, MoNₓ, AuNₓ, AgNₓ, FeNₓ, NiNₓ, and the like.

Examples of the metal chloride may include a metal chloride of the metal atoms described above. Specific examples of the metal chloride may include, but are not limited to, TiClₓ, TaClₓ, CuClₓ, CoClₓ, RuClₓ, AlClₓ, WClₓ, MoClₓ, AuClₓ, AgClₓ, FeClₓ, NiClₓ, and the like.

Examples of the metal fluoride may include a metal fluoride of the metal atoms described above. Specific examples of the metal fluoride may include, but are not limited to, TiFₓ, TaFₓ, CuFₓ, CoFₓ, RuFₓ, AlFₓ, WFₓ, MoFₓ, AuFₓ, AgFₓ, FeFₓ, NiFₓ, and the like.

The processing solution according to the present embodiment is suitable for removing an etching residue, and in particular it is more suitable for removing a dry etching residue. Usually, from the viewpoint of improving the yield of a semiconductor and preventing deterioration of electrical characteristics thereof, a dry etching residue is removed before the next step. For example, the processing solution according to the present embodiment is suitable for cleaning a semiconductor substrate after dry etching is performed in a wiring process.

### (Component (a))

The processing solution according to the present embodiment includes a compound (a) capable of releasing a fluoride anion or a salt thereof. Examples of the compound (a) may include one or more selected from the group consisting of hydrogen fluoride (HF), ammonium fluoride, and salts thereof.

The hydrogen fluoride may be blended in the form of hydrofluoric acid (aqueous solution of hydrogen fluoride) or the like. Examples of the salt of hydrogen fluoride may include a tetraalkylammonium salt, a trialkylamine salt, and the like. For example, specific examples of the salt of hydrogen fluoride may include tetrabutylammonium dihydrogen trifluoride, tetraethylammonium fluoride tetrahydrofluoride, tetraethylammonium fluoride trihydrofluoride, triethylamine pentahydrofluoride, triethylamine trihydrofluoride and the like.

The processing solution according to the present embodiment preferably does not contain hydroxylamine. In addition, the processing solution according to the present embodiment preferably does not contain a thiol-containing compound. Further, the processing solution according to the present embodiment preferably does not contain a phosphinic acid-containing compound. Further, the processing solution according to the present embodiment preferably does not contain a phosphonic acid-containing compound. Furthermore, the processing solution according to the present embodiment preferably does not contain a peroxide. The processing solution according to the present embodiment can be expected to maintain both excellent anticorrosion properties and excellent etching properties even if it does not contain the compounds. From the viewpoints, the processing solution according to the present embodiment more preferably does not contain hydroxylamine, a thiol-containing compound, a phosphinic acid-containing compound, a phosphonic acid-containing compound, and a peroxide.

The compound (a) may be used alone or in combination of two or more.

### (Component (b))

The processing solution according to the present embodiment contains a water-soluble organic solvent. The processing solution according to the present embodiment containing a water-soluble organic solvent and water described below is suitable as a so-called aqueous processing solution.

Specific examples of the water-soluble organic solvent may preferably include, but are not particularly limited to, at least one selected from the group consisting of an alcohol-based solvent, a glycol ester-based solvent, a sulfoxide-based solvent, a sulfone-based solvent, an amide-based solvent, a lactone-based solvent, an imidazolidinone-based solvent, a nitrile-based solvent, a ketone-based solvent, an ether-based solvent, an ester-based solvent, a pyrrolidone-based solvent, and a urea-based solvent. Furthermore, it is more preferable the processing solution according to the present embodiment does not contain, as the organic solvent, a solvent other than an alcohol-based solvent, a glycol ester-based solvent, a sulfoxide-based solvent, a sulfone-based solvent, an amide-based solvent, a lactone-based solvent, an imidazolidinone-based solvent, a nitrile-based solvent, a ketone-based solvent, an ether-based solvent, an ester-based solvent, a pyrrolidone-based solvent, and a urea-based solvent. When the processing solution according to the present embodiment contains an organic solvent, it is preferable to use a water-soluble organic solvent from the viewpoint of water solubility of the processing solution. Furthermore, it is preferable to use only a water-soluble organic solvent as the organic solvent.

Specific examples of the alcohol-based solvent may include aliphatic alcohols such as methanol, ethanol, modified ethanol, isopropanol, n-propanol, n-butanol, 3-methoxy-3-methyl-1-butanol, etc.; glycols such as ethylene glycol (also known as 1,2-ethanediol, monoethylene glycol), diethylene glycol (also known as 2,2′-oxydiethanol, diethyl glycol), propylene glycol (also known as propane-1,2-diol), dipropylene glycol, glycerin, 1,3-propanediol, 1,3-butanediol, 1,4-butanediol, furfuryl alcohol, hexylene glycol (also known as 2-methyl-2,4-pentanediol), etc.; and the like.

Specific examples of the glycol ester-based solvent may include ethylene-based glycol ethers such as ethylene glycol monomethyl ether, ethylene glycol dimethyl ether, diethylene glycol monomethyl ether, diethylene glycol dimethyl ether, triethylene glycol monomethyl ether, triethylene glycol dimethyl ether, ethylene glycol monoethyl ether, ethylene glycol diethyl ether, ethylene glycol monobutyl ether, ethylene glycol dibutyl ether, diethylene glycol monobutyl ether, diethylene glycol dibutyl ether, triethylene glycol monobutyl ether, triethylene glycol dibutyl ether, ethylene glycol monohexyl ether, ethylene glycol dihexyl ether, diethylene glycol monohexyl ether, diethylene glycol dihexyl ether, ethylene glycol-phenyl ether, etc.; ethylene-based glycol ether acetates such as ethylene glycol monobutyl ether acetate, diethylene glycol monobutyl ether acetate, etc.; propylene-based glycol ethers such as propylene glycol monomethyl ether (PGME), propylene glycol dimethyl ether, dipropylene glycol monomethyl ether (DPM), dipropylene glycol dimethyl ether, tripropylene glycol monomethyl ether, tripropylene glycol dimethyl ether, propylene glycol monoethyl ether, propylene glycol diethyl ether, dipropylene glycol monoethyl ether, dipropylene glycol diethyl ether, tripropylene glycol monoethyl ether, tripropylene glycol diethyl ether, propylene glycol monopropyl ether, propylene glycol dipropyl ether, dipropylene glycol monopropyl ether, dipropylene glycol dipropyl ether, propylene glycol monobutyl ether, propylene glycol dibutyl ether, dipropylene glycol monobutyl ether, dipropylene glycol dibutyl ether, tripropylene glycol monobutyl ether, tripropylene glycol dibutyl ether, propylene glycol phenyl ether, etc.; propylene-based glycol ether acetates such as propylene glycol methyl ether acetate, dipropylene glycol methyl ether acetate, propylene glycol diacetate, etc.; and the like.

Specific examples of the sulfoxide-based solvent may include dimethyl sulfoxide (DMSO), diethyl sulfoxide, dipropyl sulfoxide, diphenyl sulfoxide, thiophene, and the like.

Specific examples of the sulfone-based solvent may include dimethyl sulfone, diethyl sulfone, tetramethylene sulfone, dipropyl sulfone, sulfolane (also known as tetramethylene sulfone), 3-methylsulfolane, 2,4-dimethylsulfolane, 3,4-dimethylsulfolane, diphenylsulfolane, 3,4-diphenylmethylsulfolane, sulfolene, 3-methylsulfolene, 3-ethylsulfolene, and the like.

Specific examples of the amide-based solvent may include N,N-dimethylformamide (DMF), diethylformamide (DEF), N,N-dimethylacetamide (DMAc), N-methylpyrrolidine (MPD), hexamethylphosphate triamide (HMPA), and the like.

Specific examples of the lactone-based solvent may include γ-butyllactone, α-methyl-γ-butyrolactone, β-propiolactone, γ-valerolactone, δ-valerolactone, γ-caprolactone, ε-caprolactone, γ-laurolactone, hexanolactone, and the like.

Specific examples of the imidazolidinone-based solvent may include 2-imidazolidinone, 1,3-dimethyl-2-imidazolidinone, 1,3-diethyl-2-imidazolidinone, 1,3-dipropyl-2-imidazolidinone, 1,3-diisopropyl-2-imidazolidinone, and the like.

Specific examples of the nitrile-based solvent may include acetonitrile, propionitrile, valeronitrile, butyronitrile, and the like.

Specific examples of the ketone-based solvent may include acetone, methyl ethyl ketone (MEK), methyl isobutyl ketone (MIBK), diisobutyl ketone, cyclohexanone, diacetone alcohol, 1-hexanone, 2-hexanone, 4-heptanone, 2-heptanone (methylamyl ketone), 1-octanone, 2-octanone, 1-nonanone, 2-nonanone, acetylacetone, acetonyl acetone, phenylacetone, acetophenone, methylnaphthyl ketone, methylcyclohexanone, ionone, isophorone, propylene carbonate, diacetonyl alcohol, acetylcarbinol, and the like.

Specific examples of the ether-based solvent may include diisopropyl ether, 1,4-dioxane, methyl-tert-butyl ether (MTBE), dimethyl ether, diethyl ether, dipropyl ether, methylphenyl ether, and the like.

Specific examples of the ester-based solvent may include methyl acetate, ethyl acetate, butyl acetate, amyl acetate, propyl acetate, isopropyl acetate, methyl lactate, ethyl lactate, butyl lactate, ethyl methoxyacetate, ethyl ethoxyacetate, acetic acid 2-methoxybutyl (2-methoxybutyl acetate), acetic acid 3-methoxybutyl (3-methoxybutyl acetate), acetic acid 4-methoxybutyl (4-methoxybutyl acetate), acetic acid 3-methoxy-3-methylbutyl (3-methoxy-3-methylbutyl acetate), acetic acid 3-ethyl-3-methylbutyl (3-ethyl-3-methoxybutyl acetate), 4-methyl-4-methoxypentyl acetate, methyl formate, ethyl formate, propyl formate, butyl formate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3-ethoxypropionate, propyl-3-methoxypropionate, and the like.

Specific examples of the pyrrolidone-based solvent may include N-methyl-2-pyrrolidone (NMP), 2-pyrrolidone, N-vinyl-2-pyrrolidone, and the like.

Specific examples of the urea-based solvent may include 1,3-dimethylurea, 1,3-diethylurea, 1,3-dipropylurea, 1,3-diisopropylurea, tetramethylurea, tetraethylurea, tetrapropylurea, tetraisopropylurea, N,N-dimethylpropylene urea, and the like.

Among the above, a preferred example of the water-soluble organic solvent may preferably be at least one selected from the group consisting of dimethyl sulfoxide, N,N-dimethylformamide, N,N-dimethylacetamide, N-methyl-2-pyrrolidone, 1,3-dimethyl-2-imidazolidinone, ethylene glycol, and diethylene glycol monobutyl ether, and more preferably dimethyl sulfoxide, for example. By using these, for example, the anticorrosion properties of a layer containing a metal component such as cobalt, copper, etc. as a main component (for example, a metal wiring layer, an etching stop layer, an interlayer insulating film, another functional layer, etc.) can be further improved. That is, when the processing solution according to the present embodiment is used, damage (film loss) caused to the layer containing cobalt, copper, etc. can be more effectively reduced.

By using such a preferred solvent, for example, the anticorrosion properties of a layer containing a metal component such as copper, cobalt, tungsten, ruthenium, aluminum, molybdenum, etc. as a main component (for example, a metal wiring layer, an etching stop layer, an interlayer insulating film, another functional layer, etc.) can be further improved. That is, when such a solvent is used, both anticorrosion properties and etching properties can be maintained at high levels.

The compound (b) may be used alone or in combination of two or more.

Furthermore, it is expected that the processing solution according to the present embodiment can achieve a desired effect even if a halogen-based solvent is not used. That is, the processing solution according to the present embodiment can be used as an environment-friendly and halogen-free processing solution. From such a viewpoint, preferred examples of the processing solution according to the present embodiment may include a processing solution that does not substantially contain a halogen atom, and even a processing solution that does not contain a halogen atom. Note that “does not substantially contain” means a case where the component is inevitably blended as an impurity is not excluded. For example, the content of the component in the processing solution is preferably 1% by mass or less, more preferably 0.5% by mass or less, even more preferably 0.3% by mass or less, still even more preferably 0.1% by mass or less, and further more preferably 0% by mass.

The ratio (b/(b+c)) of the content of the component (b) to the sum of the content of the component (b) and the content of the component (c) (water) is preferably from 0.05 to 50% by mass. The lower limit of the ratio may be, for example, 0.1% by mass or more. The upper limit of the ratio is more preferably 30% by mass or less, even more preferably 20% by mass or less, and still even more preferably 10% by mass or less. By setting to the ratio as described above, the solvent can be a water-soluble mixed solvent, and higher water solubility can be imparted to the processing solution. Hence, the above ratio is preferable.

### (Component (c))

The processing solution according to the present embodiment contains water. As the water, for example, deionized water (DIW), ultrapure water (UPW), pure water, high purity ionized water, etc. can be used from the viewpoint of suitability for manufacturing a semiconductor device.

The content of the water in the processing solution according to the present embodiment is not particularly limited, but is preferably from 1 to 50% by mass. From the viewpoint that residue removal properties and anticorrosion properties can be maintained at high levels while imparting water solubility as an aqueous processing solution, the lower limit of the content thereof is more preferably 5% by mass or more, even more preferably 10% by mass or more, and still even more preferably 15% by mass or more. In addition, from the viewpoint that residue removal properties and anticorrosion properties can be maintained at high levels while imparting water solubility as an aqueous processing solution, the upper limit of the content thereof is more preferably 45% by mass or less, even more preferably 40% by mass or less, and still even more preferably 35% by mass or less. With the water content within the range described above, another component can be dissolved uniformly and stably.

The total content of the solvent is not particularly limited, but is preferably 60% by mass or more and 99.9% by mass or less. The lower limit of the total content is more preferably 70% by mass or more, even more preferably 80% by mass or more, and still even more preferably 90% by mass or more. The upper limit of the total content is more preferably 99.7% by mass or less, even more preferably 99.5% by mass or less, and still even more preferably 99.0% by mass or less. By setting the total amount of the solvent to the above range, residue removal properties and anticorrosion properties can be maintained at high levels while imparting water solubility as an aqueous processing solution. Note that the total amount of the solvent here refers to the sum of the water-soluble organic solvent, water, and another solvent. For example, when only a water-soluble organic solvent and water are used as the solvent, the total amount is the sum of the component (b) and the component (c).

### (Component (d))

The processing solution according to the present embodiment contains a nitrogen-containing aromatic compound. The processing solution according to the present embodiment has an anion content of the nitrogen-containing aromatic compound at 25° C. of 5 ppm or more and 30 ppm or less on a mass basis (ppm by mass). The lower limit of the anion content is preferably 6 ppm or more, more preferably 6.5 ppm or more, and even more preferably 7 ppm or more. The upper limit of the anion content is preferably 25 ppm or less, more preferably 20 ppm or less, and even more preferably 15 ppm or less. The anion content on a mass basis (ppm by mass, etc.) can be obtained using web software “Sparc” provided by Archem Inc. (URL: http://archemcalc.com/sparc-web/calc).

As the nitrogen-containing aromatic compound, for example, a nitrogen atom-containing anticorrosive agent may be used. The nitrogen-containing aromatic compound is preferably at least one selected from the group consisting of an imidazole ring-containing compound, a triazole ring-containing compound, a carbazole ring-containing compound, a pyridine ring-containing compound, a pyrimidine ring-containing compound, a tetrazole ring-containing compound, a pyrazole ring-containing compound, a purine ring-containing compound, and a phenanthroline ring-containing compound.

Examples of the imidazole ring-containing compound may include, for example, imidazole, 1-decyl-3-methylimidazolium chloride, 2-ethyl-4-methylimidazole, 2-methylimidazole, 2-ethylimidazole, 2-isopropylimidazole, 2-propylimidazole, 2-butylimidazole, 4-methylimidazole, 2,4-dimethylimidazole, 2-undecylimidazole, 2-aminoimidazole, 2,2′-biimidazole, and the like.

Examples of the triazole ring-containing compound may include, for example, 1,2,4-triazole (TAZ), 1,2,3-benzotriazole (BTA), 1,2,3-triazole, 3-amino-1H-1,2,4-triazole, 5-methyl-1H-benzotriazole (5MBTA), 1-hydroxybenzotriazole, 1-hydroxypropylbenzotriazole, 2,3-dicarboxypropylbenzotriazole, 4-hydroxybenzotriazole, 4-carboxyl-1H-benzotriazole, 4-carboxyl-1H-benzotriazole methyl ester, 4-carboxyl-1H-benzotriazole butyl ester, 4-carboxyl-1H-benzotriazole octyl ester, 5-hexylbenzotriazole, [1,2,3-benzotriazolyl-1-methyl][1,2,4-triazolyl-1-methyl][2-ethylhexyl]amine, tolyltriazole, naphthotriazole, bis[(1-benzotriazolyl)methyl]phosphonic acid, 3-aminotriazole, and the like.

Examples of the carbazole ring-containing compound may include, for example, 9H-carbazole, 4-hydroxycarbazole, 1-methyl-carbazole, 3-methyl-9H-carbazole, 9-methyl-1H-carbazole, 2-methoxycarbazole, 1-bromocarbazole, 2-bromocarbazole, 3-bromocarbazole, 4-bromocarbazole, 2-chlorocarbazole, 3-chlorocarbazole, 2-fluorocarbazole, 3-fluorocarbazole, 2-iodocarbazole, 3-iodocarbazole, 9-acetylcarbazole, 2,7-dibromocarbazole, 3,6-dibromocarbazole, 3,6-dichlorocarbazole, 2,3-benzcarbazole, 9-acetyl-3,6-diiodocarbazole, 2-bromo-7-methoxy-9H-carbazole, 3,6-dimethylcarbazole, 2,7-dimethylcarbazole, 3,6-diaminocarbazole, 3-amino-ethylcarbazole, 3,6-dimethoxy-9H-carbazole, 2,7-dimethoxy-9H-carbazole, 3,3′-bicarbazole, 7H-benzo[c]carbazole, and the like.

Examples of the pyridine ring-containing compound may include, for example, 4-(3-phenylpropyl)pyridine, 1H-1,2,3-triazolo[4,5-b]pyridine, 1,2,4-triazolo[4,3-a]pyridin-3(2H)-one, 3H-1,2,3-triazolo[4,5-b]pyridin-3-ol, 1-acetyl-1H-1,2,3-triazolo[4,5-b]pyridine, 3-aminopyridine, 4-aminopyridine, 3-hydroxypyridine, 4-hydroxypyridine, 2-acetamidopyridine, 4-pyrrolidinopyridine, 2-cyanopyridine, 2,2′-bipyridyl, 4,4′-dimethyl-2,2′-bipyridyl, 4,4′-di-tert-butyl-2,2′-bipyridyl, 4,4′-dinonyl-2,2′-bipyridyl, and the like.

Examples of the pyrimidine ring-containing compound may include, for example, pyrimidine, 4-methylpyrimidine, 1,2,4-triazolo[1,5-a]pyrimidine, 1,3,4,6,7,8-hexahydro-2H-pyrimido[1,2-a]pyrimidine, 1,3-diphenyl-pyrimidine-2,4,6-trione, 1,4,5,6-tetrahydropyrimidine, 2,4,5,6-tetraaminopyrimidine sulfate, 2,4,5-trihydroxypyrimidine, 2,4,6-triaminopyrimidine, 2,4,6-trichloropyrimidine, 2,4,6-trimethoxypyrimidine, 2,4,6-triphenylpyrimidine, 2,4-diamino-6-hydroxylpyrimidine, 2,4-diaminopyrimidine, 2-acetamidopyrimidine, 2-aminopyrimidine, 2-methyl-5,7-diphenyl-(1,2,4)triazolo(1,5-a)pyrimidine, 2-methylsulfanyl-5,7-diphenyl-(1,2,4)triazolo(1,5-a)pyrimidine, 2-methylsulfanyl-5,7-diphenyl-4,7-dihydro-(1,2,4)triazolo(1,5-a)pyrimidine, 4-aminopyrazolo[3,4-d]pyrimidine, and the like.

Examples of the tetrazole ring-containing compound may include, for example, 1H-tetrazole, 5-amino-1H-tetrazole, 5-methyl-1H-tetrazole, 5-phenyl-1H-tetrazole, 1-(2-diaminoethyl)-5-mercaptotetrazole, and the like.

Examples of the pyrazole ring-containing compound may include, for example, 3,5-dimethylpyrazole, 3-amino-5-methylpyrazole, 4-methylpyrazole, 3-amino-5-hydroxypyrazole, and the like.

Examples of the purine ring-containing compound may include, for example, purine, adenine, N6-benzoyladenine, and the like.

Examples of the phenanthroline ring-containing compound may include, for example, 1,10-phenanthroline, 5-amino-1,10-phenanthroline, and the like.

The component (d) may also be a salt of the compounds described above. Specific examples of the salt may include, but are not particularly limited to, a sodium salt, a potassium salt, an ammonium salt, an alkylammonium salt (for example, a tetramethylammonium salt, etc.), and the like. It may also be a hydrate of the above compounds.

The compound (d) may be used alone or in combination of two or more.

### (Component (e))

The processing solution according to the present embodiment preferably further contains (e) ammonium hydroxide. This may be blended in the form of a salt. Ammonium hydroxide may be added, for example, as ammonia water or ammonia.

### (Other Components)

The processing solution according to the present embodiment can be sufficiently expected to obtain a predetermined effect even if it does not contain any optional component other than the above-described components. As a matter of course, the processing solution according to the present embodiment may or may not contain any optional component other than the component (a) and the component (d) in addition to the solvent, as necessary. For example, when the component (d) functions as an anticorrosive agent, an anticorrosive agent other than the component (d) may be further contained. Except for the anticorrosive agent, the processing solution according to the present embodiment may further contain a pH adjuster, a surfactant, and the like, but it may not contain these components since a sufficient effect can be expected even if these are not contained. Further, the processing solution according to the present embodiment may contain a metal impurity described later as long as an mechanism or effect thereof can be obtained.

### (Buffer)

The processing solution according to the present embodiment may contain a buffer. A buffer is a compound that has a mechanism of inhibiting a change in the pH of a processing solution. By containing a buffer, the processing solution can be efficiently controlled such that the pH value of the processing solution is smaller than the acid dissociation constant. In addition, by containing a buffering agent, the processing solution can be efficiently controlled such that the pH of the processing solution is at a predetermined value. The buffer is not particularly limited as long as it is a compound having pH buffering ability.

Examples of the buffer may include Good's buffer. Examples of Good's buffer may include 3-cyclohexylaminopropanesulfonic acid (CAPS), N-tris(hydroxymethyl)methyl-3-aminopropanesulfonic acid (TAPS), 4-(cyclohexylamino)-1-butanesulfonic acid (CABS), tricine, bicine, 2-morpholinoethanesulfonic acid monohydrate (MES), bis(2-hydroxyethyl)aminotris(hydroxymethyl)methane (Bis-Tris), N-(2-acetamido)iminodiacetic acid (ADA), piperazine-1,4-bis(2-ethanesulfonic acid) (PIPES), N-(2-acetamido)-2-aminoethanesulfonic acid (ACES), 2-hydroxy-3-morpholinopropanesulfonic acid (MOPSO), N,N-bis(2-hydroxyethyl)-2-aminoethanesulfonic acid (BES), N-tris(hydroxymethyl)methyl-2-aminoethanesulfonic acid (TES), 2-[4-(2-hydroxyethyl)-1-piperazinyl]ethanesulfonic acid (HEPES), piperazine-1,4-bis(2-hydroxypropanesulfonic acid) (POPSO), 4-(2-hydroxyethyl)piperazine-1-(2-hydroxypropane-3-sulfonic acid) (HEPSO), 4-(2-hydroxyethyl)-1-piperazinepropanesulfonic acid (EPPS), and the like.

The buffer may be used alone or in combination of two or more. Alternatively, the processing solution according to the present embodiment may not contain a buffer.

### (Surfactant)

The processing solution according to the present embodiment may contain a surfactant for the purpose of adjusting wettability of the processing solution to a substrate; and the like. Examples of the surfactant may include a nonionic surfactant, an anionic surfactant, a cationic surfactant, an amphoteric surfactant, etc.

Examples of the nonionic surfactant may include a polyalkylene oxide alkyl phenyl ether-based surfactant, a polyalkylene oxide alkyl ether-based surfactant, a block polymer-based surfactant composed of polyethylene oxide and polypropylene oxide, a polyoxyalkylene distyrenated phenyl ether-based surfactant, a polyalkylene tribenzyl phenyl ether-based surfactant, an acetylene polyalkylene oxide-based surfactant, and the like.

Examples of the anionic surfactant may include alkyl sulfonic acid, alkyl benzene sulfonic acid, alkyl naphthalene sulfonic acid, alkyl diphenyl ether sulfonic acid, fatty acid amide sulfonic acid, polyoxyethylene alkyl ether carboxylic acid, polyoxyethylene alkyl ether acetic acid, polyoxyethylene alkyl ether propionic acid, alkyl phosphonic acid, fatty acid, a salt thereof, and the like. Examples of the salt may include, but are not particularly limited to, a sodium salt, a potassium salt, an ammonium salt, an alkylammonium salt (e.g., a tetramethylammonium salt, etc.), and the like.

Examples of the cationic surfactant may include an alkylpyridium-based surfactant, a quaternary ammonium salt-based surfactant, and the like.

Examples of the amphoteric surfactant may include a betaine-type surfactant, an amino acid-type surfactant, an imidazoline-type surfactant, an amine oxide-type surfactant, and the like.

These surfactants are generally commercially available. These surfactants may be used alone or in combination of two or more.

When the processing solution according to the present embodiment contains a surfactant, the content of the surfactant is not particularly limited and is preferably from 0.0001% by mass to 5% by mass with respect to the total mass of the processing solution, for example. The lower limit of the content thereof is more preferably 0.0002% by mass or more, and even more preferably 0.002% by mass or more. The upper limit of the content thereof is more preferably 3% by mass or less, even more preferably 1% by mass or less, and still even more preferably 0.2% by mass or less.

The processing solution according to the present embodiment may not contain one or more selected from the group consisting of the nonionic surfactant, the anionic surfactant, the cationic surfactant, and the amphoteric surfactant, and may not contain one or more of the above compounds exemplified as these surfactants. The processing solution according to the present embodiment may not contain a surfactant.

### (pH Adjuster)

The processing solution according to the present embodiment may contain a pH adjuster in order to adjust to a desired pH. As the pH adjuster, an inorganic acid, an organic acid, an organic basic compound, and an inorganic basic compound can be appropriately used.

### (Impurity, Etc.)

The processing solution according to the present embodiment may contain a metal impurity containing at least one metal atom selected from the group consisting of a Fe atom, a Cr atom, a Ni atom, a Zn atom, a Ca atom, a Pb atom, etc., for example.

The total content of the metal atom in the processing solution according to the present embodiment is preferably 100 ppt by mass or less with respect to the total mass of the processing solution. The lower the lower limit of the total content of the metal atom, the more preferable it is. For example, the lower limit may be 0.001 ppt by mass or more. The total content of the metal atom may for example be from 0.001 to 100 ppt by mass. The total content of the metal atom equal to or lower than the above preferred upper limit improves defect suppression properties and residue suppression properties of the processing solution. It is considered that, with the total content of the metal atom equal to or higher than the above preferred lower limit, the metal atom is less likely to be a free atom in the system and less likely to have a negative impact on the production yield of an entire object to be cleaned (However, the mechanism and effect according to the present embodiment are not limited thereto.).

The content of the metal impurity can be adjusted by, for example, a purification process such as filtering, etc. The purification process such as filtering, etc. may be performed on a part or all of the raw materials before preparation of the processing solution, or may be performed after preparation of the processing solution.

The processing solution according to the present embodiment may contain, for example, an impurity derived from an organic substance (organic impurity). The total content of the above organic impurity in the processing solution according to the present embodiment is preferably 5000 ppm by mass or less. The lower the lower limit of the total content of the organic impurity, the more preferable it is. For example, the lower limit may be 0.1 ppm by mass or more. Examples of the total content of the organic impurity may include a total content from 0.1 to 5000 ppm by mass.

The processing solution according to the present embodiment may contain an object to be counted of such a size as counted by a light scattering liquid-borne particle counter, for example. The size of the object to be counted is, for example, 0.04 μm or more. The number of the object to be counted contained in the processing solution according to the present embodiment is, for example, 1,000 or less per 1 mL of the processing solution, and the lower limit thereof is, for example, 1 or more. It is considered that the number of the object to be counted in the processing solution within the above-described range improves a metal corrosion suppression effect of the processing solution.

The organic impurity and/or the object to be counted may be added to the processing solution or may be inevitably mixed in the processing solution in the manufacturing process of the processing solution. As non-limiting examples of the case that the organic impurity and/or the object to be counted is inevitably mixed in the processing solution in the manufacturing process of the processing solution, the organic impurity may be contained in a raw material (for example, an organic solvent) used for manufacturing the processing solution, or may be mixed in from an external environment in the manufacturing process of the processing solution (for example, contamination).

In the case that the object to be counted is added to the processing solution, the abundance ratio may be adjusted for each specific size in consideration of the surface roughness of an object to be cleaned, and the like.

The processing solution according to the present embodiment can be used for various purposes. Among them, from the viewpoint that the effect and advantage of the present embodiment can be effectively utilized, the processing solution according to the present embodiment is suitable as a solution for processing a substrate after etching that includes a first metal atom-containing layer containing a copper atom, and a second metal atom-containing layer containing an aluminum atom or a cobalt atom. Examples of the substrate may include a copper-based substrate for manufacturing a semiconductor, and the like.

Furthermore, the processing solution according to the present embodiment is suitable as a solution for processing a substrate after etching that includes a first metal atom-containing layer containing a copper atom, a second metal atom-containing layer containing an aluminum atom, and a third metal atom-containing layer containing a cobalt atom. Examples of the substrate may include a copper-based substrate for manufacturing a semiconductor, and the like.

Here, an exemplary semiconductor substrate to which the processing solution according to the present embodiment can be used will be described.

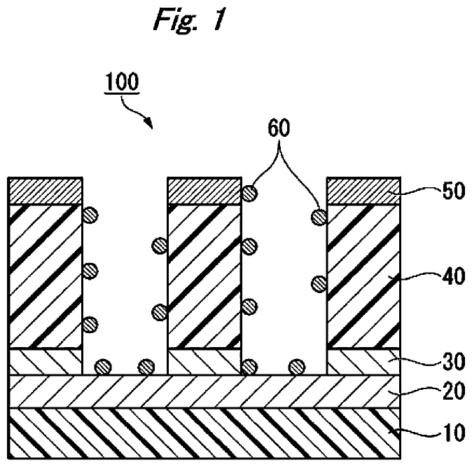

FIG. 1 is a cross-sectional view illustrating an example of an element (semiconductor substrate) after dry etching to be processed (cleaned).

A semiconductor element 100 illustrated in FIG. 1 includes a substrate 10, a metal wiring layer 20, an etching stop layer 30, and an interlayer insulating film 40, which are laminated in this order, and a hard mask layer (HM layer) 50 is formed on the interlayer insulating film 40 (substrate 10/metal wiring layer 20/etching stop layer 30/interlayer insulating film 40/HM layer 50).

The semiconductor element 100 has been subjected to dry etching in a wiring process. That is, the semiconductor element 100 is in a state after the dry-etching of the interlayer insulating film 40 by using as a mask the HM layer 50 having a basic shape of a wiring pattern formed by dry etching. Dry etching residues 60 are adhered to side surfaces of the HM layer 50 and the interlayer insulating film 40. Although a case where etching is performed by dry etching is described here as an example, when etching is performed by wet etching, the resultant residue is a wet etching residue.

The metal wiring layer 20 is exposed to spaces in the interlayer insulating film 40 in the shape of the wiring pattern, and the dry etching residues 60 are also adhered.

As the substrate 10, for example, a substrate made of a material such as silicon, amorphous silicon, glass, or the like can be used.

The metal wiring layer 20 is a wiring layer containing one of metals such as molybdenum (Mo), tungsten (W), ruthenium (Ru), copper (Cu), gold (Au), silver (Ag), iron (Fe), nickel (Ni), aluminum (Al), lead (Pb), zinc (Zn), tin (Sn), tantalum (Ta), magnesium (Mg), cobalt (Co), bismuth (Bi), cadmium (Cd), titanium (Ti), zirconium (Zr), antimony (Sb), manganese (Mn), beryllium (Be), chromium (Cr), germanium (Ge), vanadium (V), gallium (Ga), hafnium (Hf), indium (In), niobium (Nb), rhenium (Re), thallium (Tl), etc. and a metal oxide, a metal nitride, a metal chloride, a metal fluoride, etc. thereof.

Note that the metal wiring layer 20 is not limited to wiring and broadly includes those functioning as a functional layer such as an electrode, an insulating layer, a low dielectric layer, and various conductor layers. It includes a layer formed by using the metals mentioned above and a metal oxide, a metal nitride, etc. thereof.

A material of the interlayer insulating film 40 may be any material as long as it has insulating properties. The material is not particularly limited, and a suitable material may be appropriately selected in consideration of a manufacturing condition and the like. As the interlayer insulating film 40, for example, a layer containing a silicon-based material such as SiO₂, SiN, SiOC, SiOCN, etc. can be used.

A material of the HM layer 50 may be any material as long as it acts as a protective film against etching. The material is not particularly limited, and a suitable material may be appropriately selected in consideration of a manufacturing condition and the like. The processing solution according to the present embodiment can efficiently remove a residue generated from the HM layer (refer to the dry etching residue 60).

The dry etching residue 60 includes, for example, an etching residue containing the above-described inorganic substance, and the like.

### <Processing Method>

The processing solution according to the present embodiment can be suitably used as a method for processing a substrate. The processing method is for a processing for removing a residue generated after etching from a substrate. A preferred examples of the processing method of the present embodiment may be a method for processing a substrate, including: processing a substrate after etching using the processing solution described above at a temperature of 20° C. or more and less than 30° C., in which the substrate includes a first metal atom-containing layer containing a copper atom, and a second metal atom-containing layer containing an aluminum atom or a cobalt atom. The substrate may be a substrate having the above-mentioned structure.

Another preferred example of the processing method according to the present embodiment may be a method for processing a substrate, including: processing a substrate after etching using the processing solution described above at a temperature of 20° C. or more and less than 30° C., in which the substrate includes a first metal atom-containing layer containing a copper atom, a second metal atom-containing layer containing an aluminum atom, and a third metal atom-containing layer containing a cobalt atom. The substrate may be a substrate having the above-mentioned structure.

The processing method according to the present embodiment is a step of processing (cleaning) the semiconductor element 100 after dry etching is performed in a wiring process, using the processing solution described above. A method for implementing the cleaning is not particularly limited, and a known cleaning method can be used. As an example, a case of cleaning the semiconductor element 100 illustrated in FIG. 1 will be described.

When bringing the processing solution into contact with the semiconductor element 100 to be cleaned, the processing solution may be diluted 2 to 2000 times to obtain a diluted solution, and a cleaning operation may then be performed using the diluted solution.

Examples of the cleaning operation may include a method of continuously discharging the processing solution on the semiconductor element 100 rotating at a constant speed (rotational application method), a method of immersing the semiconductor element 100 in the processing solution for a certain period of time (dipping method), a method of spraying the processing solution on a surface of the semiconductor element 100 (spraying method), and the like.

The processing temperature of the processing solution is preferably 20° C. or more and less than 30° C. By using the processing solution according to the present embodiment for the processing within the temperature range, it is possible to achieve both anticorrosion properties of copper (a metal atom-containing layer having a copper atom) and etching properties of aluminum (a metal atom-containing layer having an aluminum atom) at higher levels. Furthermore, in the case of a substrate including a metal atom-containing layer having a cobalt atom, it is expected that anticorrosion properties of copper, etching properties of aluminum, and etching properties of cobalt can be achieved at higher levels. Although the reason therefor is not certain, it is presumed as follows. An anticorrosive agent for metal corrosion tends to be more strongly adsorbed to copper, cobalt, etc. than to aluminum, etc., and it is considered that anticorrosion properties by an anticorrosive agent for metal corrosion exceeds corrosion of copper or cobalt by an etching agent particularly in the temperature range of 20° C. or more and less than 30° C., and therefore the above-mentioned effects such as selectivity, etc. can be obtained (However, the mechanism and effect according to the present embodiment are not limited thereto.).

Processing time of the processing solution can be appropriately selected so as to be sufficient for removing an etching residue, an impurity, and the like adhered on a surface of the semiconductor element 100. For example, the cleaning time is preferably from 10 seconds to 30 minutes. The lower limit of the cleaning time is more preferably 20 seconds or more, and even more preferably 30 seconds or more. The upper limit of the cleaning time is more preferably 15 minutes or less, even more preferably 10 minutes or less, and still even more preferably 5 minutes or less.

Since the processing solution according to the present embodiment is used for cleaning, in the semiconductor element 100 to which the dry etching residues 60 are adhered, the dry etching residues 60 derived from the HM layer 50, which is a protective film, can be well cleaned and removed while damage to the metal wiring layer 20 of copper, cobalt, or the like is suppressed.

In addition, by using the processing solution according to the present embodiment, damage to various functional layers (metal wiring layer 20, etching stop layer 30, interlayer insulating film 40, etc.) other than the protective film can be suppressed.

Furthermore, since the processing solution according to the present embodiment is also expected to obtain practicable degree of cleaning effects without using a conventional general-purpose hydroxylamine or the like, it can be expected that an semiconductor element, etc. can be manufactured more safely.

### <Method for Manufacturing a Semiconductor>

The processing solution according to the present embodiment and the processing method using the same can be suitably used as a method for manufacturing a semiconductor. A preferred example of the method for manufacturing a semiconductor according to the present embodiment may be, for example, a method for manufacturing a semiconductor substrate, including: etching a substrate; ashing the etched substrate; and processing the ashed substrate using the processing solution described above at a temperature of 20° C. or more and less than 30° C., in which the substrate includes a first metal atom-containing layer containing a copper atom, and a second metal atom-containing layer containing an aluminum atom or a cobalt atom. The above-mentioned conditions may be adopted for the processing step using the processing solution.

Another preferred example of the method for manufacturing a semiconductor according to the present embodiment may be a method for manufacturing a semiconductor substrate, including: etching a substrate; ashing the etched substrate; and processing the ashed substrate using the processing solution described above at a temperature of 20° C. or more and less than 30° C., in which the substrate includes a first metal atom-containing layer containing a copper atom, a second metal atom-containing layer containing an aluminum atom, and a third metal atom-containing layer containing a cobalt atom. The above-mentioned conditions may be adopted for the processing step using the processing solution.

For the etching step, a known method and condition may be adopted. For example, the above-mentioned etching technique may be adopted. For example, in the case of etching of aluminum, plasma etching using a halogen-containing gas such as carbon tetrachloride, etc. may be adopted.

For the ashing step, a known method and condition may be adopted. For example, oxygen plasma may be adopted.

Here, the method for manufacturing a semiconductor will be described by taking as an example a case of cleaning the semiconductor element 100 illustrated in FIG. 1.

The method for manufacturing a semiconductor of this case is a method for manufacturing a semiconductor that includes, for example, (1) a step of preparing a substrate having a protective film, (2) a step of etching the protective film, and (3) a step of removing an impurity from the substrate by bringing the above processing solution into contact with the substrate, after the etching. For example, in the case of the semiconductor element 100 (semiconductor substrate) illustrated in FIG. 1, the HM layer 50 corresponds to the protective film, as in the description of the processing method (cleaning method). Hereinafter, a case of cleaning the semiconductor element 100 illustrated in FIG. 1 will be described as an example.

### (1) Step of Preparing a Substrate Having a Protective Film

In step (1), a substrate having at least a protective film is prepared. Although not illustrated, in the case of FIG. 1, a laminate before etching that has in this order a substrate 10, a metal wiring layer 20, an etching stop layer 30, an interlayer insulating film 40, and a hard mask layer (HM layer) 50 corresponding to a protective film is prepared (substrate 10/metal wiring layer 20/etching stop layer 30/interlayer insulating film 40/HM layer 50).

A method for sequentially laminating the metal wiring layer 20, the etching stop layer 30, the interlayer insulating film 40, and the hard mask layer (HM layer) 50 corresponding to the protective film, on the substrate 10 is not particularly limited, and a known method can be employed.

### (2) Step of Etching the Protective Film

Subsequently, the protective film is subject to etching. An etching method is not particularly limited, may be wet etching or dry etching, but is preferably dry etching. Dry etching is advantageous from the viewpoints that a metal wiring at nano level is possible, and gas used can be controlled. In the case of dry etching, there is a concern that damage to the substrate, etc. is relatively large, but from the viewpoint that such damage can be effectively suppressed by using the processing solution according to the present embodiment, dry etching is also desirable in a point that the advantage of the present embodiment can be more effectively reflected.

In the case of dry etching, plasma can be used. Usually, when plasma etching is performed, there is a problem that the substrate is easily damaged, or a problem that plasma etching generates a plasma etching residue and it is necessary to clean it with a processing solution. However, dry etching is also preferable in a point that such problems can be effectively suppressed by using the processing solution according to the present embodiment.

(3) Step of Removing an Impurity from the Substrate by Bringing the Above Processing Solution into Contact with the Substrate, after the Etching

As the step (3), the processing methods (cleaning methods) described above can be used. Thereby, the semiconductor element 100 can be obtained. As necessary, a known post-processing can be performed after the cleaning.

As described above, the processing solution according to the present embodiment can be used, for example, as a processing solution for removing a residue generated in a semiconductor etching step, etc., and is, in particular, suitable for removing a residue generated by dry etching. The processing solution according to the present embodiment has an advantage that it has both anticorrosion properties of copper (a metal layer containing a copper atom) and excellent etching properties of aluminum (a metal layer containing an aluminum atom). Furthermore, in the case of a substrate having a layer containing a cobalt atom, it can also be expected to achieve an advantage of excellent anticorrosion properties of cobalt (a metal layer containing a cobalt atom).

Furthermore, when a conventionally used processing solution (for example, a processing solution containing hydroxylamine, etc.) is used, there may be a problem such as large damage to copper (that is, a large amount of film loss). However, since the processing solution according to the present embodiment has excellent anticorrosion properties of copper, the occurrence of such a defect can be effectively suppressed. In addition, the processing solution according to the present embodiment can also be expected to have excellent anticorrosion properties for highly versatile metal materials such as copper, cobalt, etc. Hence, the processing solution according to the present embodiment is also suitable in that it can be expected to reduce damage to a substrate, a metal wiring, an etching stop layer, an interlayer insulating film, and various other functional layers that contain copper, cobalt, etc. as a metal component. On the other hand, the processing solution according to the present embodiment is also suitable as a processing solution having excellent etching properties for a metal layer that contains aluminum, etc. as a metal component.

Furthermore, since the processing solution according to the present embodiment can be a halogen-free processing solution, not only is it environmentally friendly, but it can also be used easily in terms of ease of disposal.

### Examples

The present invention will be described in more detail with reference to the following Examples and Comparative examples, but the present invention is not limited in any way to the following examples.

### 1. Test 1

### 1-1. Preparation of Processing Solutions

Processing solutions were obtained by blending the components shown in Table 1 in the proportion shown in Table 1. The kinds of the “anticorrosive agent” in Table 1 were the components shown in Table 2. For example, Comparative example 1 is an aqueous processing solution containing (a) 1.0% by mass (mass %) of ammonium fluoride, (d) no nitrogen atom-containing anticorrosive agent, (c) 30.0% by mass of water, and (b) dimethyl sulfoxide as an aqueous organic solvent as the balance. Example 1 is an aqueous processing solution containing (a) 1.0% by mass of ammonium fluoride, (c) 30.0% by mass of water, (d) 1,2,4-triazole as a nitrogen atom-containing anticorrosive agent with the anion concentration of 14 ppm, and (b) dimethyl sulfoxide as an aqueous organic solvent as the balance.

The anion concentration of the anticorrosive agent of each processing solution of Examples and Comparative examples was determined using web software “Sparc” provided by Archem Inc. (URL: http://archemcalc.com/sparc-web/calc).

### 1-2. Evaluation of Anticorrosion Properties (Film Loss) of Copper (Cu)

First, a laminate (a substrate having a film) was prepared by a CVD method, in which a Ta layer (thickness of 20 nm) and a Cu layer (thickness of 30 nm) were laminated in this order on a substrate (12-inch SiO₂ substrate) in cross-sectional view. (Substrate/Ta layer/Cu layer). The laminate was cut into 2 cm×2 cm in top view to fabricate test samples (wafer coupons).

Subsequently, 80 mL of each processing solution of Examples and Comparative examples was poured into a 100 mL cup. A test sample was placed and immersed in each processing solution at 25° C. for 15 minutes. During the immersion, each processing solution was stirred at 300 rpm. After the immersion, the sample was taken out from the processing solution, washed with water at room temperature for 30 seconds, and dried by nitrogen blowing.

Then, the film thicknesses of each sample before and after the immersion in the processing solution were measured. By determining the difference as the amount of change in film thickness, the film loss was determined.

### 1-3. Evaluation of Anticorrosion Properties (Film Loss) of Cobalt (Co)

First, a laminate (a substrate having a film) was prepared by the CVD method, in which a TiN layer (thickness of 20 nm) and a Co layer (thickness of 100 nm) were laminated in this order on a substrate (12-inch silicon substrate) in cross-sectional view (Substrate/TiN layer/Co layer). The laminate was cut into 2 cm×2 cm in top view to fabricate test samples (wafer coupons).

Subsequently, 80 mL of each processing solution of Examples and Comparative examples was poured into a 100 mL cup. A test sample was placed and immersed in each processing solution at 25° C. for 15 minutes. During the immersion, each processing solution was stirred at 300 rpm. After the immersion, the sample was taken out from the processing solution, washed with water at room temperature for 30 seconds, and dried by nitrogen blowing.

Then, the film thicknesses of each sample before and after the immersion in the processing solution were measured. By determining the difference as the amount of change in film thickness, the film loss was determined.

### 1-4. Evaluation of Etching Properties (Film Loss) of Aluminum (Al)

First, a laminate (a substrate having a film) was prepared by the CVD method, in which an aluminum layer (thickness of 50 nm) was formed on a substrate (12-inch silicon substrate) in cross-sectional view (substrate/Al layer). The laminate was cut into 2 cm×2 cm in top view to fabricate test samples (wafer coupons).

Subsequently, 80 mL of each processing solution of Examples and Comparative examples was poured into a 100 mL cup. A test sample was placed and immersed in each processing solution at 25° C. for one minute. During the immersion, each processing solution was stirred at 300 rpm. After the immersion, the sample was taken out from the processing solution, washed with water at room temperature for 30 seconds, and dried by nitrogen blowing.

Then, the film thicknesses of each sample before and after the immersion in the processing solution were measured. By determining the difference as the amount of change in film thickness, the film loss was determined.

Table 1 shows the base composition of the processing solutions of Examples and Comparative examples. Table 2 shows the ppm concentration (on a mass basis) of the anion of the component (d), and the evaluation results of Examples and Comparative examples.

The abbreviations in the tables are as follows:
DMSO: dimethyl sulfoxide
MOPS: 3-morpholinopropanesulfonic acid
CHES: 2-cyclohexylaminoethanesulfonic acid
Taurine: 2-aminoethanesulfonic acid
TAPS: N-tris(hydroxymethyl)methyl-3-aminopropanesulfonic acid
TAPSO: N-[tris(hydroxymethyl)methyl]-3-aminopropanesulfonic acid
HEDPA: 1-hydroxyethane-1,1-diylbis(phosphonic acid)
TAZ: 1,2,4-triazole

TABLE 1
Composition

| Compound | [wt %] |
|---|---|
| (a) Ammonium fluoride | 1.0 |
| (b) DMSO | Balance |
| (c) Water | 30.0 |
| (d) Anticorrosive agent | 0.1 to 1.4 |

TABLE 2

| | | Anion content of | Film loss of | Film loss of | Film loss of |
|---|---|---|---|---|---|
| | (d) Anticorrosive | nitrogen-containing | Cu substrate [nm] | Co substrate [nm] | Al substrate [nm] |
| | agent name | aromatic compound [ppm] | 25° C. · 15 min. | 25° C. · 15 min. | 25° C. · 1 min. |
| Comparative | No anticorrosive | 0 | 3.2 | 8.6 | 5.0 |
| example 1 | agent | | | | |
| Comparative | Thioglycerol | 0 | 1.0 | 13.9 | 4.5 |
| example 2 | | | | | |
| Comparative | 1-Decanethiol | 0 | 1.7 | 4.3 | 4.2 |
| example 3 | | | | | |
| Comparative | MOPS | 0 | 3.8 | 8.7 | 4.8 |
| example 4 | | | | | |
| Comparative | CHES | 0 | 3.2 | 9.6 | 3.3 |
| example 5 | | | | | |
| Comparative | Taurine | 0 | 2.2 | 8.4 | 3.7 |
| example 6 | | | | | |
| Comparative | TAPS | 0 | 5.2 | 11.0 | 4.3 |
| example 7 | | | | | |
| Comparative | TAPSO | 0 | 6.4 | 8.8 | 3.9 |
| example 8 | | | | | |
| Comparative | HEDPA | 0 | 1.6 | 16.3 | 4.8 |
| example 9 | | | | | |
| Example 1 | TAZ | 14 | <0.5 | <0.5 | 5.6 |
| Example 2 | Imidazole | 14 | <0.5 | <0.5 | 4.4 |
| Example 3 | 4-(3-Phenylpropyl)pyridine | 14 | <0.5 | <0.5 | 5.3 |

### 2. Test 2

The anion concentration of the anticorrosive agent (d) of each processing solution was varied to evaluate anticorrosion properties of copper (Cu ER), anticorrosion properties of cobalt (Co ER), and etching properties of aluminum (Al ER).

### 2-1. Preparation of Processing Solutions

Processing solutions containing the components listed in Table 3 were each prepared with the anion concentration of 1,2,4-triazole, which was a nitrogen atom-containing anticorrosive agent (d), as shown in Table 4. For example, Comparative example 10 is an aqueous processing solution containing (a) 1.0% by mass of ammonium fluoride, (d) no 1,2,4-triazole, (c) 30.0% by mass of water, and (b) dimethyl sulfoxide as an aqueous organic solvent as the balance. Example 4 is an aqueous processing solution containing (a) 1.0% by mass of ammonium fluoride, (c) 30.0% by mass of water, (d) 1,2,4-triazole with the anion concentration of 7 ppm, and (b) dimethyl sulfoxide as an aqueous organic solvent as the balance.

### 2-2. Evaluation of Anticorrosion Properties

In accordance with the method of Test 1, anticorrosion properties of copper (Cu ER), anticorrosion properties of cobalt (Co ER), and etching properties of aluminum (Al ER) were evaluated.

Table 3 shows the base composition of the processing solutions of Examples and Comparative examples.

TABLE 3
Composition

| Compound | [wt %] |
|---|---|
| (a) Ammonium fluoride | 1.0 |
| (b) DMSO | Balance |
| (c) Water | 30.0 |
| (d) 1,2,4-Triazole | 0 to 0.5 |

Table 4 shows the ppm concentration of the anion of the component (d) and the etching rate (A/min) upon 15 minutes of immersion at 25° C. as an evaluation of damage to Cu using a Cu substrate for Examples and Comparative examples. The etching rate was measured using XRF (Rigaku Corporation, “ZSX Primus IV”), and the film loss per time was measured by dividing the film loss determined by the above method by the immersion time.

TABLE 4

| | | Cu damage evaluation |
|---|---|---|
| | (d) 1,2.4-Triazole | using Cu substrate |
| | anion concentration | ER @ 25° C. · 15 min. |
| | [ppm] | [A/min] |
| Comparative example 10 | 0 | 2.5 |
| Comparative example 11 | 0.14 | 2.6 |
| Comparative example 12 | 1.4 | 0.7 |
| Example 4 | 7 | 0.4 |
| Example 5 | 14 | 0.3 |
| Comparative example 13 | 70 | 0.6 |

Table 5 shows the ppm concentration of the anion of the component (d) and the etching rate (A/min) upon 15 minutes of immersion at 25° C. as an evaluation of damage to Co using a Co substrate for Examples and Comparative examples. The etching rate was measured using XRF (Rigaku Corporation, “ZSX Primus IV”), and the film loss per time was measured by dividing the film loss determined by the above method by the immersion time.

TABLE 5

| | | Co damage evaluation |
|---|---|---|
| | (d) 1.2,4-Triazole | using Co substrate |
| | anion concentration | ER @ 25° C. · 15 min. |
| | [ppm] | [A/min] |
| Comparative example 10 | 0 | 5.1 |
| Comparative example 11 | 0.14 | 6.1 |
| Comparative example 12 | 1.4 | 3.5 |
| Example 4 | 7 | 0.5 |
| Example 5 | 14 | 0.3 |
| Comparative example 13 | 70 | 0.5 |

Table 6 shows the ppm concentration of the anion of the component (d) and the etching rate (A/min) upon one minute of immersion at 25° C. as an evaluation of etching on Al using an Al substrate for Examples and Comparative examples. The etching rate was measured using XRF (Rigaku Corporation, “ZSX Primus IV”), and the film loss per time was measured by dividing the film loss determined by the above method by the immersion time.

TABLE 6

| | | Al etching evaluation |
|---|---|---|
| | (d) 1,2,4-Triazole | using Al substrate |
| | anion concentration | Film loss @ 25° C. · |
| | [ppm] | 1 min. [A/min] |
| Comparative | 0 | 50 |
| example 10 | | |
| Comparative | 0.14 | 50 |
| example 11 | | |
| Comparative | 1.4 | 48 |
| example 12 | | |
| Example 4 | 7 | 51 |
| Example 5 | 14 | 52 |
| Comparative | 70 | 56 |
| example 13 | | |

### 3. Test 3

The anion concentration of the anticorrosive agent (d) of each processing solution was varied to evaluate damage to copper using a copper pattern wafer.

### 3-1. Preparation of Processing Solutions

Processing solutions containing the components listed in Table 7 were each prepared with the anion concentration of 1,2,4-triazole, which was a nitrogen atom-containing anticorrosive agent (d), as shown in Table 8. For example, Comparative example 14 is an aqueous processing solution containing (a) 1.0% by mass of ammonium fluoride, (d) no 1,2,4-triazole, (c) 30.0% by mass of water, and (b) dimethyl sulfoxide as an aqueous organic solvent as the balance. Example 6 is an aqueous processing solution containing (a) 1.0% by mass of ammonium fluoride, (c) 30.0% by mass of water, (d) 1,2,4-triazole with the anion concentration of 11 ppm, and (b) dimethyl sulfoxide as an aqueous organic solvent as the balance.

### 3-2. Evaluation of Anticorrosion Properties (Film Loss) of Copper (Cu)

First, a laminate (a substrate having a film) was prepared by the CVD method, in which a Ta layer (thickness of 20 nm) and a Cu layer (thickness of 30 nm) were laminated in this order on a substrate (12-inch silicon substrate) in cross-sectional view. (Substrate/Ta layer/Cu layer). The laminate was cut into 2 cm×2 cm in top view to fabricate test samples (wafer coupons).

Subsequently, 80 mL of each processing solution of Examples and Comparative examples was poured into a 100 mL cup. A test sample was placed and immersed in each processing solution at 25° C. for 5 minutes. During the immersion, each processing solution was stirred at 300 rpm. After the immersion, the sample was taken out from the processing solution, washed with water at room temperature for 30 seconds, and dried by nitrogen blowing.

Then, the presence or absence of corrosion of the Cu pattern was evaluated using an ultra-high resolution field emission scanning electron microscope (manufactured by Hitachi, Ltd., “SU8220”) based on the following criteria:
A: Corrosion was not confirmed over almost the entire surface of the Cu pattern.
B: Corrosion was confirmed locally on part of the Cu pattern.
C: Corrosion was confirmed over almost the entire surface of the Cu pattern.

Table 7 shows the base composition of the processing solutions of Examples and Comparative examples. Table 8 shows the evaluation results of corrosion of the Cu pattern wafers of Examples and Comparative Examples.

TABLE 7
Composition

| Compound | [wt %] |
|---|---|
| (a) Ammonium fluoride | 1.0 |
| (b) DMSO | Balance |
| (c) Water | 30.0 |
| (d) 1,2,4-Triazole | 0 to 0.5 |

TABLE 8

| | (d) 1,2,4-Triazole | Corrosion of Cu |
|---|---|---|
| | anion concentration | pattern wafer |
| | [ppm] | 25° C. · 5 min. |
| Comparative example 14 | 0 | C |
| Example 6 | 11 | A |
| Example 7 | 14 | A |
| Example 8 | 28 | A |
| Comparative example 15 | 35 | B |
| Comparative example 16 | 42 | B |
| Comparative example 17 | 56 | B |
| Comparative example 18 | 70 | B |

From the above, it was confirmed that the processing solutions according to Examples are excellent in at least the anticorrosion properties of copper and the etching properties of aluminum. Such processing solutions can be suitably used in a method for processing a substrate, and a method for manufacturing a semiconductor.

The present application claims priority to U.S. Provisional Application No. 63/593,081, filed with the United States Patent and Trademark Office on Oct. 25, 2023, the contents of which are incorporated herein by reference.

### EXPLANATION OF REFERENCE SIGNS

10: Substrate
20: Metal wiring layer
30: Etching stop layer
40: Interlayer insulating film
50: Hard mask layer (HM layer)
60: Dry etching residue
100: Semiconductor element (semiconductor substrate)

1. A processing solution, comprising:
(a) a compound capable of releasing a fluoride anion or a salt thereof;
(b) a water-soluble organic solvent;
(c) water; and
(d) a nitrogen-containing aromatic compound,
wherein an anion content of the nitrogen-containing aromatic compound at 25° C. is 5 ppm or more and 30 ppm or less.

2. The processing solution according to claim 1, further comprising:
(e) ammonium hydroxide.

3. The processing solution according to claim 1,
wherein (b) the water-soluble organic solvent comprises at least one selected from the group consisting of: dimethyl sulfoxide, N,N-dimethylformamide, N,N-dimethylacetamide, N-methyl-2-pyrrolidone, 1,3-dimethyl-2-imidazolidinone, ethylene glycol, and diethylene glycol monobutyl ether.

4. The processing solution according to claim 1,
wherein (d) the nitrogen-containing aromatic compound comprises at least one selected from the group consisting of: an imidazole ring-containing compound, a triazole ring-containing compound, a carbazole ring-containing compound, a pyridine ring-containing compound, a pyrimidine ring-containing compound, a tetrazole ring-containing compound, a pyrazole ring-containing compound, a purine ring-containing compound, and a phenanthroline ring-containing compound.

5. The processing solution according to claim 1,
wherein a total solvent content is 60% by mass or more and 99.9% by mass or less.

6. The processing solution according to claim 1,
wherein the processing solution is a solution for processing a substrate after etching, and
the substrate comprises a first metal atom-containing layer containing a copper atom, and a second metal atom-containing layer containing an aluminum atom or a cobalt atom.

7. The processing solution according to claim 1,
wherein the processing solution is a solution for processing a substrate after etching, and
the substrate comprises a first metal atom-containing layer containing a copper atom, a second metal atom-containing layer containing an aluminum atom, and a third metal atom-containing layer containing a cobalt atom.

8. A method for processing a substrate, comprising:
processing a substrate after etching using the processing solution according to claim 1 at a temperature of 20° C. or more and less than 30° C.,
wherein the substrate comprises a first metal atom-containing layer containing a copper atom, and a second metal atom-containing layer containing an aluminum atom or a cobalt atom.

9. A method for processing a substrate, comprising:
processing a substrate after etching using the processing solution according to claim 1 at a temperature of 20° C. or more and less than 30° C.,
wherein the substrate comprises a first metal atom-containing layer containing a copper atom, a second metal atom-containing layer containing an aluminum atom, and a third metal atom-containing layer containing a cobalt atom.

10. A method for manufacturing a semiconductor substrate, comprising:
etching a substrate;
ashing the etched substrate; and
processing the ashed substrate using the processing solution according to claim 1 at a temperature of 20° C. or more and less than 30° C.,
wherein the substrate comprises a first metal atom-containing layer containing a copper atom, and a second metal atom-containing layer containing an aluminum atom or a cobalt atom.

11. A method for manufacturing a semiconductor substrate, comprising:
etching a substrate;
ashing the etched substrate; and
processing the ashed substrate using the processing solution according to claim 1 at a temperature of 20° C. or more and less than 30° C.,
wherein the substrate comprises a first metal atom-containing layer containing a copper atom, a second metal atom-containing layer containing an aluminum atom, and a third metal atom-containing layer containing a cobalt atom.
